(19) United States
(12) Patent Application Publication
(10) Pub. No.: US 2009/0006015 A1
(43) Pub. Date: Jan. 1, 2009

(54) Method and apparatus for measuring current density in conductive materials

(76) Inventors: Frederick M. Mueller, Los Alamos, NM (US); Holger Grube, Gaithersburg, MD (US); Geoffrey W. Brown, Los Alamos, NM (US); Marilyn E. Hawley, Los Alamos, NM (US); J. Yates Coulter, Santa Fe, NM (US)

Correspondence Address: LOS ALAMOS NATIONAL SECURITY, LLC, LOS ALAMOS NATIONAL LABORATORY, PPO. BOX 1663, LC/IP, MS A187, LOS ALAMOS, NM, 87545, US

(21) Appl. No.: 11/824,650

(22) Filed: Jun. 29, 2007

(51) Int. Cl. G01R 19/08; G01R 33/09

(52) U.S. Cl. 702/65; 324/252

(57) ABSTRACT

The present invention relates to an apparatus and method for measuring a current density in a conductive material. The apparatus and method use an algorithm and an extension to the Fourier transform approach that allows transport currents to be treated accurately. Due to its speed, the resulting algorithm is ideally suited for high-resolution and high-throughput magnetic imaging of superconducting tape in real time.

### STATEMENT REGARDING FEDERAL RIGHTS

This invention was made with government support under Contract No. DE-AC52-06NA25396, awarded by the U.S. Department of Energy. The government has certain rights in the invention.

### BACKGROUND OF INVENTION

The invention relates to measuring the current density of a conductor. More particularly, the invention relates to a method and apparatus for measuring the current density within a conductor; Even more particularly, the invention relates to a method and apparatus for measuring the current density within a conductor using an inversion algorithm.

Superconducting coated conductor tapes can replace conventional conductors in electrical power applications such as transformers, motors, and generators to improve energy efficiency and reduce size. High and consistent current carrying capability is the prime target for coated conductor manufacturing.

Electric currents flowing in a conductor generate magnetic fields in the surrounding space. Under certain conditions, internal current densities can be derived from a measurement of the external magnetic fields. Currents confined to flow in a thin flat film such as in coated conductor tape can be derived from magnetic field maps that are scanned parallel to the film. Several approaches for inversion of the magnetic field component in the z direction (B_{Z}), which is the component that is most easily measured, have previously been developed. All of these approaches have disadvantages of being incommensurate with transport current, tending to diverge in some situations, or having limited speed.

Current methods of determining the current density in a conductor involve inversion schemes that introduce too much error or are too slow to permit high resolution and high throughput imaging of conductors—particularly superconductors—in real time. Therefore, a method of determining the real-time current density in a high throughput conductor is desirable. What is also desirable is an apparatus for determining the current density in real time.

### SUMMARY OF INVENTION

The present invention provides an apparatus and method for measuring a current density in a conductive material. The apparatus and method use an algorithm and an extension to the Fourier transform approach that allows transport currents to be treated accurately. Due to its speed, the resulting algorithm is ideally suited for high-resolution and high-throughput magnetic imaging of superconducting tape in real time.

Accordingly, one aspect of the invention is to provide an apparatus for measuring current density in a conductive material. The apparatus includes: a power supply, wherein the power supply supplies a transport current through the conductive material; a probe comprising a magnetic sensor for measuring a magnetic field perpendicular to a surface of the conductive material, wherein the sensor generates an output signal; a scanning assembly for positioning at least one of the probe and the conductive material at a predetermined distance from each other; and a processor in communication with the sensor, wherein the processor applies an algorithm to the output signal generated by the sensor to calculate a current density for the conductive material.

A second aspect of the invention is to provide a sensor assembly for detecting a magnetic field surrounding a conductive material. The sensor includes: a probe comprising a magneto-resistive sensor, wherein the magneto-resistive sensor generates an output signal corresponding to a distribution of a magnetic field that is generated when a transport current is passed through the conductive material; a scanning assembly coupled to the probe, wherein the scanning assembly positions at least one of the probe and the conductive material at a predetermined position and a predetermined distance from each other; and a processor in communication with the sensor, wherein the processor deconvolutes the distribution of the magnetic field with an inversion algorithm to calculate a current density for the conductive material.

A third aspect of the invention is to provide an apparatus for measuring current density in a conductive material. The apparatus includes: a power supply, wherein the power supply supplies a transport current through the conductive material; a probe comprising a magneto-resistive sensor, wherein the magneto-resistive sensor generates an output signal corresponding to a distribution of a magnetic field that is generated when the transport current is passed through the conductive material; a scanning assembly coupled to the probe, wherein the scanning assembly positions at least one of the probe and the conductive material at a predetermined position and a predetermined distance from each other; and a processor in communication with the sensor, wherein the processor deconvolutes the distribution of the magnetic field with an inversion algorithm to calculate a current density for the conductive material, wherein the inversion algorithm is

$${b}_{z} ( k ) = i {μ}_{0} \cdot \frac{d}{2} \cdot \frac{k}{{k}_{r}} {e}^{- h \vert k \vert} \cdot {j}_{X} ( k )$$

where b_{z} is the component of magnetic field perpendicular to the plane of the conductor, i is the square root of −1(\sqrt{1}), μₒ is the permeability of free space, 4π×10⁻⁷ henry per meter (H/m) in scientific international (SI) units, d is the tape thickness, k is \sqrt{kₓ²+k_{y}²} and kₓ and k_{y} are wave numbers in the x and y direction respectively, and h is the height at which the magnetic field is measured above the tape.

A fourth aspect of the invention is to provide a method of determining the current density of a conductive material. The method includes the steps of: providing the conductive material; supplying a transport current through the conductive material; measuring a distribution of a magnetic field that is generated by the transport current passing through the conductive material; and deconvoluting the magnetic field distribution to determine the current density.

A fifth aspect of the invention is to provide a method of determining the current density of a conductive material. The method includes the steps of: providing the conductive material; supplying a transport current through the conductive material; positioning a probe at a predetermined distance from a surface of the conductive material, wherein the probe comprises a magnetic sensor capable of detecting a distribution of a magnetic field generated by the transport current; and deconvoluting the magnetic field distribution to determine the current density.

These and other aspects, advantages, and salient features of the present invention will become apparent from the following detailed description, the accompanying drawings, and the appended claims.

### BRIEF DESCRIPTION OF THE DRAWINGS

FIG. 1 is a flow chart of a method for determining the current density of a conductive material;

FIG. 2 is another flow chart of a method for determining the current density of a conductive material;

FIG. 3 is a schematic representation showing the relationship between the magentoresistive sensor and the conductive material;

FIG. 4 is a schematic representation of an imaging apparatus of the present invention; and

FIG. 5 is a plot of current densities for conductive yttrium barium copper oxide tapes obtained using the imaging apparatus and inversion algorithms of the prior art and the present invention.

### DETAILED DESCRIPTION

In the following description, like reference characters designate like or corresponding parts throughout the several views shown in the figures. It is also understood that terms such as “top,” “bottom,” “outward,” “inward,” and the like are words of convenience and are not to be construed as limiting terms. In addition, whenever a group is described as either comprising or consisting of at least one of a group of elements and combinations thereof, it is understood that the group may comprise or consist of any number of those elements recited, either individually or in combination with each other.

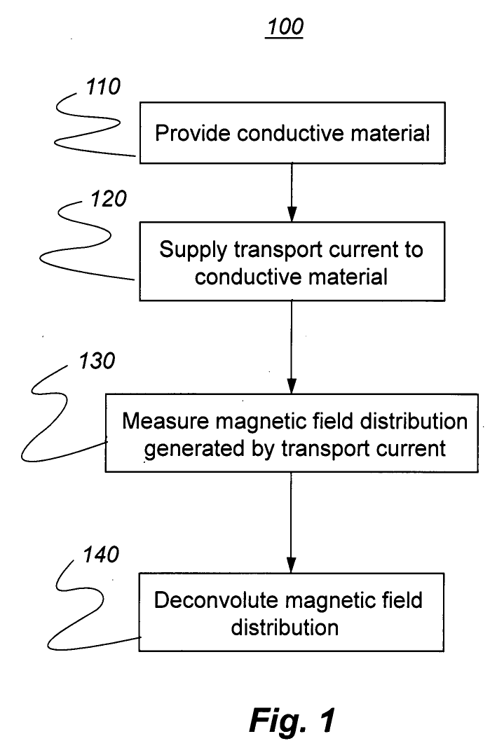

Referring to the drawings in general and to FIG. 1 in particular, it will be understood that the illustrations are for the purpose of describing a particular embodiment of the invention and are not intended to limit the invention thereto.

The invention provides a method, outlined in the flow chart shown in FIG. 1, of determining the current density of a conductive material. In Step 110, a conductive material is provided. In one embodiment, the conductive material is a high temperature superconducting (HTS) tape such as, for example, a tape comprising superconducting yttrium barium copper oxide (YBCO). Such tapes typically comprise an alloy substrate, at least one ceramic buffer layer, a high temperature superconducting layer, and a protective metallic overlayer. While a superconducting tape is specifically described herein, other conductive materials such as, but not limited to, good metals such as copper, poor metals such as iron or highly resistive alloys, and semiconductors such as germanium or gallium arsinide (GaAs), may be provided. When the conductor is a superconductor, the conductor is cryogenically cooled to a temperature at which the conductive material is in a superconductive state. For example, the conductive material may be cooled to a temperature below either the boiling point of liquid argon (88 K) or liquid nitrogen (77 K). Other cryogenic liquids may be used to cool at either higher or lower temperatures.

In Step 120, a transport current is supplied through the conductive material. The transport current may be less or greater than the critical current of the superconductor present in the conductive material. Transport currents of up to 280 A have been applied to conductive materials while determining the current density of the conductive material.

The passage of the transport current through the conductive material generates a magnetic field, which is measured in Step 130. The magnetic field may be measured by at least one sensor that is capable of detecting the magnetic field. Such sensors are described elsewhere herein.

The generated magnetic field is a convolution of the spatial distribution of current densities. In Step 140, the magnetic field distribution is deconvoluted to determine the current density. Deconvolution of the magnetic field distribution to derive the current density distribution is carried out using an inversion algorithm based upon the Biot-Savart law, which relates the magnetic field B to the current density j. By assuming that the conductor is much thinner than wide and much longer than wide (thickness:width:length=1 μm:1 cm:1 m), and that the current density is uniform across the thickness, the Biot-Savart law can be expressed for the thin film geometry in k-space:

$${b}_{z} ( k ) = {iμ}_{0} \cdot \frac{d}{2} \cdot \frac{k}{{k}_{Y}} {e}^{- h \vert k \vert} \cdot {j}_{X} ( k )$$

where b_{z} is the component of magnetic field perpendicular to the plane of the conductor, i is the square root of −1 (\sqrt{1}), μₒ is the permeability of free space 4π+10⁻⁷ in scientific international (SI) units, d is the tape thickness, k is \sqrt{kₓ²+k_{y}²} and kₓ and k_{y} are wave numbers in the x and y direction respectively, and h is the height at which the magnetic field is measured above the tape. This relationship is free of integrals and provides for an efficient avenue to solve for the current density j_{X}. A similar expression holds for the other current density component j_{Y}.

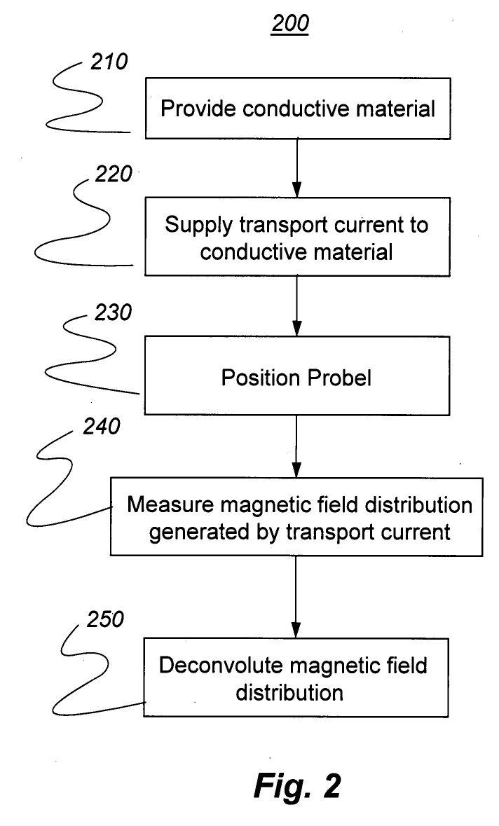

A second method of determining the current density in a conductive material is also provided. FIG. 2 is a flow chart of method 200. The steps of providing a conductive material (Step 210) and supplying a transport current through the conductive material (Step 220) are identical to those of method 100 and have been previously described. In Step 230, a probe is positioned at a predetermined distance from the conductive material while the transport current is being supplied through the conductive material. The probe includes a magnetic sensor that is capable of detecting a magnetic field that is generated by the transport current passing through the conductive material (Step 240). In one embodiment, the magnetic sensor is a magnetoresistant sensor such as, but not limited to, an anisotropic magnetoresistant sensor or a giant magnetoresistant sensor. Examples of such sensors include, but are not limited to, a Hall probe, a flux gate magnetometer, a superconducting quantum interference device (SQUID), a magneto-optic sensor, a magnetic force microscopic head, a coil inductor, and the like.

In one embodiment, the magnetic sensor is a sensing element that is commonly used in hard drive read heads. Such sensing elements have a suitable magnetic field range and a small sensitive area, are capable of operation at cryogenic temperatures, are rugged, economical, and are readily available. Sensing elements of various constructions (anisotropic magnetoresistive and giant magnetoresistive) and sizes (300 nanometers by 80 nanometers to 5 micrometers by 120 nanometers) have been used for magnetic field detection and measurement. The spacing between the magnetic sensor head and the conductive material determines the achievable resolution of the magnetic field maps that are ultimately obtained by the method. Spacings in a range from 10 micrometers to 5 mm have been demonstrated, although other spacings could be used as well. In one embodiment, the spacing is maintained by disposing a spacer between the magnetic sensor and conductive material. The spacer comprises an electrically non-conductive plastic such as Kapton® polyimide film or the like. The spacers work best if they are non-conductive and non-magnetic.

In one embodiment, the method further comprises the step of scanning or translating the probe across a surface of the conductive material to obtain a spatial map of the magnetic field distribution. In one embodiment, the probe is scanned across the surface by means of a pivotable arm, where the probe is located at one end of the arm. In another embodiment, the probe may be coupled to a stage that translates the probe along x and y axes. Alternatively, the conductive sample may be coupled to either a pivotable arm or a translating stage while the probe remains stationary.

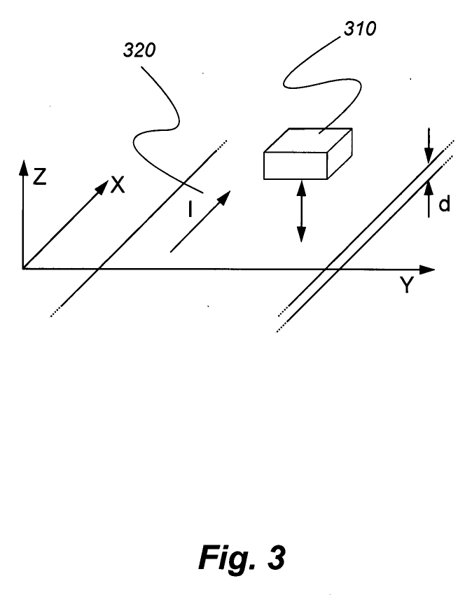

The relationship between the magentoresistive sensor and the conductive material is schematically shown in FIG. 3. Magnetoresistive sensor 310 is maintained at a predetermined distance h from conductive material 320, through which a transport current I is passed, while scanned along the x and y axes across the surface of magnetoresistive sensor 320. As previously described, a spacer (not shown) may be used to maintain distance h between magnetoresistive sensor 310 and conductive material 320.

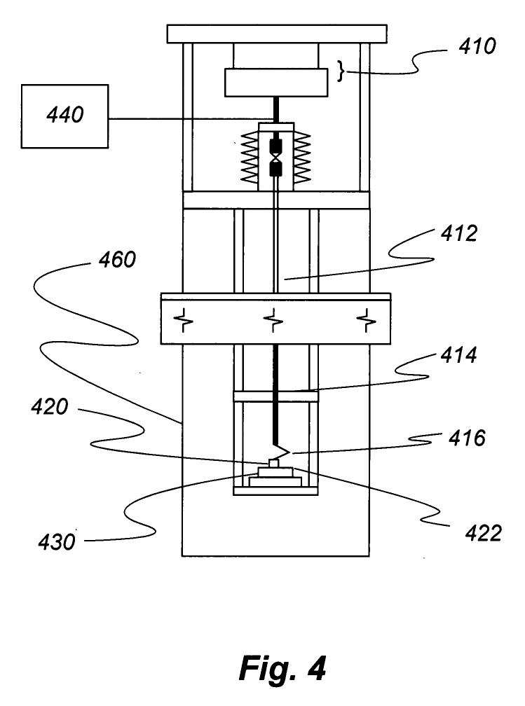

The invention also includes an imaging apparatus for measuring current density using the methods described hereinabove. A schematic representation of the imaging apparatus is shown in FIG. 4. Apparatus 400 includes a probe, which comprises a scan rod 412 and sensor 420. In one embodiment, a sample 430 of the conductive material and sensor 420 are immersed in dewar 460 containing a cryogenic fluid, such as liquid nitrogen or liquid argon. Sensor 420 is attached to a spring 416 mounted at the bottom of scan rod 412. The opposite end of scan rod 412 is rastered by a high resolution x-y scanner 410. A fixed pivot point 414 located near sensor 420 translates the motion of x-y scanner 410 by a factor of 5. An electrically non-conductive spacer 422 is positioned between sensor 420 and sample 430 to maintain a fixed distance between sensor 420 and sample 430, and to prevent damage to sample 430 during the rastering or scanning motion. In one embodiment, spacer is an electrically non-conductive plastic such as Kapton® polyimide film or the like. Before scanning, pivot rod 412 is lowered towards sample 430 so that tension in spring 416 keeps sensor in contact with spacer 422, thereby maintaining sensor 420 at a fixed distance from sample 430. Spring 416 may be any resilient metal or alloy strip that may be adapted to maintain tension at temperatures at which measurements are carried out. A power supply (not shown) provides a transport current through sample 430 while sensor 420 is rastered across the surface of sample 430. The power supply may be either an AC or DC power supply.

Communication between sensor 420 and processor 440 is established by means that are well known in the art. Such means include, but are not limited to, electric wiring or cable, optical or fiber optic means, wireless transmission and reception means, and the like. The magnetic field measured by sensor 420 is transmitted to processor 440, which inverts the Biot-Savart law using Fourier space techniques and the equation described hereinabove, to yield current density maps of sample 430.

The following example illustrates the features and advantages of the present invention and is no way intended to limit the invention thereto.

### EXAMPLE 1

Current densities for conductive YBCO tapes were obtained using the imaging apparatus described herein and shown in FIG. 4. The conductive YBCO tapes consist of a 100 micrometer thick nickel alloy substrate, a textured ceramic buffer layer deposited using an ion beam assisted deposition (IBAD) technique, a high-temperature superconducting (HTS) layer, and a 3 micrometer thick protective silver overlayer. The HTS layer was fabricated by metal organic vapor deposition (MOCVD) and pulsed laser deposition (PLD). The thickness of each of the buffer and HTS layers was in the range of 1-2 micrometers.

A magnetoresistive sensor was scanned a small height h above the superconducting tape sample. The sensor generated an output signal based on the component b_{Z} of the magnetic field perpendicular to the plane of the tape. The sensor signal was recorded on an equispaced grid spanning a travel of twice the tape width in both the x (along the tape) and y (across the tape) directions. The equispaced grid typically consists of typically 256×256 points. The conductor samples were 10 mm wide. The sample was positioned such that magnetic maps of 20 mm×20 mm were acquired with the coated conductor centered and 5 mm of current-free empty space was imaged on either side of the tape. A programmable DC power supply provided transport current to the sample. The overvoltage protection feature of the power supply removed the current when the tape voltage exceeded 50 mV, preventing thermal destruction of a normal going sample. In order to avoid imaging of trapped magnetic flux in the superconductor during imaging, transport currents were applied in ascending order, beginning at 0 A and concluding with the highest current before thermal runaway occurs. Since the highest current is typically above the critical current I_{C} at 1 μV/cm, samples were also deliberately tested under significant dissipation.

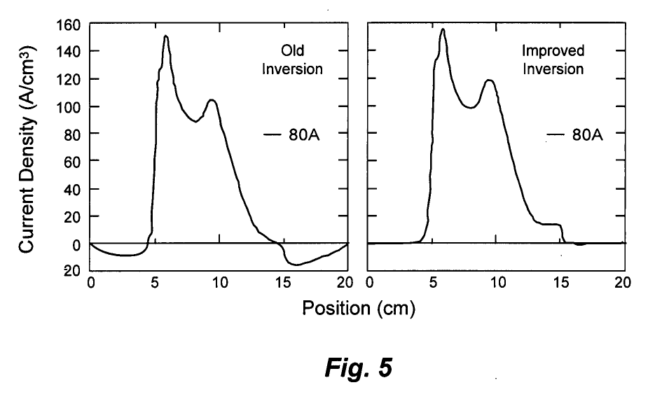

Current density profiles were derived according to the earlier approach of Roth et al., “Using a magnetometer to image a two-dimensional current distribution”, J. Appl. Phys., 65(1), 1989, 361-372 and with the inversion algorithm of the present invention, described herein. Current density profiles obtained using both approaches are plotted in FIG. 5. Both inversion procedures give overall asymmetric current distribution plots; the current density is high in the left portion of the sample, whereas the right edge of the conductor has only a fraction of the current density.

Both inversion algorithms gave double peaked current density profiles and both showed that the right half of the sample carried less current than the left half. The double-peaked structure at a transport current of 80 A indicates that the conductive tape had not yet reached its critical current, which was determined in a separate measurement to be 110 A. The sharp slope in the current density plot near the left tape edge suggests that the material there is an excellent superconductor with a high current density. The rather shallow slope and the generally lower current density on the right half of the sample point to growth problems that could be related to materials properties or reduced thickness of the deposited HTS layer.

The inversion achieved with the prior approach of Roth et al. produces negative current densities outside the tape from 0-5 mm and from 15-20 mm. Portions of the current density plot near the edges of the tape are also very distorted, making analysis of the plot near the right tape edge difficult. Additional conclusions cannot be drawn with confidence. In contrast, the inversion algorithm of the present invention does not appear to suffer from the same distortions. As expected, the current density is near zero outside the HTS portion of the tape. Moreover, the inversion algorithm of the present invention indicates that the current density of the outer 2 mm along the right edge is nearly constant. This behavior is consistent with an asymmetric temperature profile during HTS deposition, leading to good material in the left half of the conductive portion of the tape, where the substrate temperature may be high enough to form mostly stoichiometric, c-axis oriented YBCO, mixed quality YBCO right of the center axis of the tape, and only a-axis oriented or non-stoichiometric material in the right most 2 mm of the tape.

While typical embodiments have been set forth for the purpose of illustration, the foregoing description should not be deemed to be a limitation on the scope of the invention. Accordingly, various modifications, adaptations, and alternatives may occur to one skilled in the art without departing from the spirit and scope of the present invention.

1. An apparatus for measuring current density in a conductive material, the apparatus comprising:
a) a power supply, wherein the power supply supplies a transport current through the conductive material;
b) a probe, the probe comprising a magnetic sensor for measuring a magnetic field perpendicular to a surface of the conductive material, wherein the sensor generates an output signal;
c) a scanning assembly for positioning at least one of the probe and the conductive material at a predetermined distance from each other; and
d) a processor in communication with the sensor, wherein the processor applies an algorithm to the output signal generated by the sensor to calculate a current density for the conductive material.

2. The apparatus according to claim 1, wherein the algorithm is
$${b}_{z} ( k ) = {iμ}_{0} \cdot \frac{d}{2} \cdot \frac{k}{{k}_{Y}} {e}^{- h \vert k \vert} \cdot {j}_{X} ( k )$$
where b_{z} is the component of magnetic field perpendicular to the plane of the conductor, i is the square root of −1 (\sqrt{1}), μₒ is the permeability of free space, 4π×10⁻⁷ in scientific international (SI) units, d is the tape thickness, k is \sqrt{kₓ²+k_{y}²} and kₓ and k_{y} are wave numbers in the x and y direction respectively, and h is the height at which the magnetic field is measured above the tape.

3. The apparatus according to claim 1, further including a spacer disposed between the magnetic sensor and the conductive material, wherein the spacer maintains a predetermined distance between the magnetic sensor and the conductive material.

4. The apparatus according to claim 1, wherein the magnetic sensor is a magnetoresistant sensor.

5. The apparatus according to claim 3, wherein the magnetoresistant sensor is one of an anisotropic magnetoresistant sensor and a giant magnetoresistant sensor.

6. The apparatus according to claim 1, wherein the magnetoresistant sensor is one of a Hall probe, a flux gate magnetometer, a superconducting quantum interference device, a magneto-optic sensor, a magnetic force microscopic head, or a coil inductor.

7. The apparatus according to claim 1, wherein the scanning assembly includes a pivotable arm, and wherein one of the conductive material and the magnetic the sensor is located at a first end of the pivotable arm.

8. The apparatus according to claim 1, wherein the scanning assembly includes a stage that is capable of translating one of the conductive material and the magnetic sensor along at least two axes.

9. The apparatus according to claim 1, wherein the power supply is a DC power supply.

10. The apparatus according to claim 1, wherein the power supply is an AC power supply.

11. The apparatus according to claim 1, further including a cryostat for maintaining the apparatus and the conductive material at a temperature below about 20° C.

12. A sensor assembly for detecting a magnetic field surrounding a conductive material, the sensor comprising:
a) a probe, the probe comprising a magneto-resistive sensor, wherein the magneto-resistive sensor generates an output signal corresponding to a distribution of a magnetic field that is generated when a transport current is passed through the conductive material;
b) a scanning assembly coupled to the probe, wherein the scanning assembly positions at least one of the probe and the conductive material at a predetermined position and a predetermined distance from each other;
c) a processor in communication with the sensor, wherein the processor deconvolutes the distribution of the magnetic field with an inversion algorithm to calculate a current density for the conductive material.

13. The sensor assembly according to claim 12, wherein the algorithm is
$${b}_{z } ( k ) = {iμ}_{0} \cdot \frac{d}{2} \cdot \frac{k}{{k}_{Y}} {e}^{- h \vert k \vert} \cdot {j}_{X} ( k )$$
where b_{z} is the component of magnetic field perpendicular to the plane of the conductor, i is the square root of −1 (\sqrt{1}), μₒ is the permeability of free space 4π×10⁻⁷ in scientific international (SI) units, d is the tape thickness, k is \sqrt{kₓ²+k_{y}²} and kₓ and k_{y} are wave numbers in the x and y direction respectively, and h is the height at which the magnetic field is measured above the tape.

14. An apparatus for measuring current density in a conductive material, the apparatus comprising:
a) a power supply, wherein the power supply supplies a transport current through the conductive material;
b) a probe, the probe comprising a magneto-resistive sensor, wherein the magneto-resistive sensor generates an output signal corresponding to a distribution of a magnetic field that is generated when the transport current is passed through the conductive material;
c) a scanning assembly coupled to the probe, wherein the scanning assembly positions at least one of the probe and the conductive material at a predetermined position and a predetermined distance from each other; and
d) a processor in communication with the sensor, wherein the processor deconvolutes the distribution of the magnetic field with an inversion algorithm to calculate a current density for the conductive material, wherein the inversion algorithm is
$${b}_{z } ( k ) = {iμ}_{0} \cdot \frac{d}{2} \cdot \frac{k}{{k}_{Y}} {e}^{- h \vert k \vert} \cdot {j}_{X} ( k )$$
where b_{z} is the component of magnetic field perpendicular to the plane of the conductor, i is the square root of −1 (\sqrt{1}), μₒ is the permeability of free space 4π×10⁻⁷ in scientific international (SI) units, d is the tape thickness, k is \sqrt{kₓ²+k_{y}²} and kₓ and k_{y} are wave numbers in the x and y direction respectively, and h is the height at which the magnetic field is measured above the tape.

15. A method of determining the current density of a conductive material, the method comprising the steps of:
a) providing the conductive material;
b) supplying a transport current through the conductive material;
c) measuring a distribution of a magnetic field that is generated by the transport current passing through the conductive material; and
d) deconvoluting the magnetic field distribution to determine the current density.

16. The method according to claim 15, wherein the transport current is in a range from about 50 A to about 1000 A.

17. The method according to claim 15, wherein the step of measuring the distribution of a magnetic field that is generated by the transport current comprises positioning a probe comprising a magnetic sensor at a predetermined distance from the conductive material.

18. The method according to claim 15, further comprising the step of scanning the probe across the surface of the conductive material to obtain a spatial map of the magnetic field distribution.

19. The method according to claim 15, wherein the magnetic sensor is one of an anisotropic magnetoresistant sensor and a giant magnetoresistant sensor.

20. The method according to claim 15, wherein the step of deconvoluting the magnetic field distribution to determine the current density comprises deconvoluting the magnetic field density using an inversion algorithm, wherein the inversion algorithm is
$${b}_{z } ( k ) = {iμ}_{0} \cdot \frac{d}{2} \cdot \frac{k}{{k}_{Y}} {e}^{- h \vert k \vert} \cdot {j}_{X} ( k )$$
where b_{z} is the component of magnetic field perpendicular to the plane of the conductor, i is the square root of −1 (\sqrt{1}), μₒ is the permeability of free space 4π×10⁻⁷ in scientific international (SI) units, d is the tape thickness, k is \sqrt{kₓ²+k_{y}²} and kₓ and k_{y} are wave numbers in the x and y direction respectively, and h is the height at which the magnetic field is measured above the tape.

21. The method according to claim 15, further including the step of cryogenically cooling the conductive material to a temperature below a predetermined temperature.

22. The method according to claim 15, wherein the predetermined temperature is in a range from about 4 K to about 88 K.

23. The method according to claim 15, wherein the conductive material is a conductive tape comprising a superconducting oxide.

24. A method of determining the current density of a conductive material, the method comprising the steps of:
a) providing the conductive material;
b) supplying a transport current through the conductive material;
c) positioning a probe at a predetermined distance from a surface of the conductive material, wherein the probe comprises a magnetic sensor capable of detecting a distribution of a magnetic field generated by the transport current; and
d) deconvoluting the magnetic field distribution to determine the current density.
